(19) United States
(12) Patent Application Publication
(10) Pub. No.: US 2026/0243952 A1
(43) Pub. Date: Aug. 20, 2026

(54) SEMICONDUCTOR OPTICAL INTEGRATED ELEMENT

(71) Applicant: Mitsubishi Electric Corporation, Tokyo (JP)

(72) Inventor: Takahiko KIMURA, Tokyo (JP)

(73) Assignee: Mitsubishi Electric Corporation, Tokyo (JP)

(21) Appl. No.: 19/159,302

(22) PCT Filed: Apr. 26, 2023
(86) PCT No.: PCT/JP2023/016374

§ 371 Date: Aug. 22, 2025

(51) Int. Cl. G02B 6/122; H01S 5/026; H01S 5/20

(52) U.S. Cl. CPC G02B 6/122; H01S 5/0265; H01S 5/2018

(57) ABSTRACT

A semiconductor optical integrated element includes a laser diode portion that includes a first optical waveguide and generates laser light, a separation portion connected to the laser diode portion and including a second optical waveguide that has a first core layer to propagate laser light emitted from the laser diode portion, and an optical modulator portion connected to the separation portion and including a third optical waveguide that has a second core layer to absorb a part of the laser light. The third optical waveguide has a constant thickness in a direction perpendicular to a face of a substrate on which the optical modulator portion is formed, and a proportion of the second core layer in a cross section of the third optical waveguide perpendicular to a propagation direction of the laser light increases from an incident side of the laser light toward an emission side.

### TECHNICAL FIELD

The present disclosure relates to a semiconductor optical integrated element.

### BACKGROUND ART

As an example of a conventional semiconductor optical integrated element, a semiconductor optical integrated element is known in which an optical waveguide of an optical modulator portion and an optical waveguide of a separation portion between a laser diode and the optical modulator portion have the same layer structure along an optical axis direction, that is, the structure in which cross-sectional shapes with respect to an optical axis are the same. In addition, in order to reduce the concentration of the light absorption current in the vicinity of the light incident end face of the optical modulator portion, for example, Patent Document 1 discloses a technique of reducing the concentration of the light absorption current on the light incident end face portion by introducing a non-doped layer into the optical modulator portion and further making the thickness thereof thick on the light incident side and thin on the emission side.

### CITATION LIST

### Patent Document

Patent Document 1: Japanese Patent Application Laid-Open No. 2001-24289

### SUMMARY OF THE INVENTION

### Problem to be Solved by the Invention

However, the technique disclosed in Patent Document 1 is intended to suppress the light absorption current by reducing the applied reverse bias voltage by the non-doped layer, and is not intended to suppress the intensity of light itself incident on the light absorption layer. Further, since the intensity of light emitted from the laser diode portion is the highest near the center in the optical axis direction, in the optical modulator portion having a structure in which the light absorption layer is disposed near the center in the optical axis direction in the light incident end face, the light absorption current in the vicinity of the light incident end face cannot be sufficiently suppressed, and the light absorption current is likely to concentrate in a microscopic region. That is, in the conventional semiconductor optical integrated element, there is a problem in that the light absorption current concentrates on the microscopic region due to light with intensity staying high incident on the light absorption layer in the vicinity of the light incident end face of the optical modulator portion, and thus the characteristics of the semiconductor optical integrated element may degrade.

### Means for Solving the Problem

A semiconductor optical integrated element according to the present disclosure includes a laser diode portion that includes a first optical waveguide and generates laser light, a separation portion connected to the laser diode portion and including a second optical waveguide that has a first core layer to propagate laser light emitted from the laser diode portion, and an optical modulator portion connected to the separation portion and including a third optical waveguide that has a second core layer to absorb a part of the laser light emitted from the separation portion. The third optical waveguide has a constant thickness in a direction perpendicular to a face of a substrate on which the optical modulator portion is formed, and a proportion of the second core layer in a cross section of the third optical waveguide perpendicular to a propagation direction of the laser light increases from an incident side of the laser light toward an emission side of the laser light.

### Effect of Invention

According to the present disclosure, the concentration of the light absorption current in the vicinity of the incident end face of the optical modulator portion can be reduced as compared with conventional products, allowing the semiconductor optical integrated element to suppress the occurrence of characteristic degradation.

### BRIEF DESCRIPTION OF THE DRAWINGS

FIG. 1 is a schematic top view of a semiconductor optical integrated element according to Embodiment 1.

FIG. 2 is a schematic cross-sectional view taken along line G-G of the semiconductor optical integrated element according to Embodiment 1.

FIG. 3 is a schematic cross-sectional view taken along line A-A of the semiconductor optical integrated element according to Embodiment 1.

FIG. 4 is a schematic cross-sectional view taken along line B-B and line C-C of the semiconductor optical integrated element according to Embodiment 1.

FIG. 5 is a schematic cross-sectional view taken along line D-D of the semiconductor optical integrated element according to Embodiment 1.

FIG. 6 is a schematic cross-sectional view taken along line E-E of the semiconductor optical integrated element according to Embodiment 1.

FIG. 7 is a schematic cross-sectional view taken along line F-F of the semiconductor optical integrated element according to embodiment 1.

FIG. 8 is a schematic cross-sectional view taken along line D-D of a semiconductor optical integrated element according to Embodiment 2.

FIG. 9 is a schematic cross-sectional view taken along line E-E of the semiconductor optical integrated element according to Embodiment 2.

FIG. 10 is a schematic cross-sectional view taken along line G-G of the semiconductor optical integrated element according to Embodiment 2.

FIG. 11 is a schematic top view of a semiconductor optical integrated element according to Embodiment 3.

FIG. 12 is a schematic cross-sectional view taken along line B-B of the semiconductor optical integrated element according to Embodiment 3.

FIG. 13 is a schematic cross-sectional view taken along line C-C of the semiconductor optical integrated element according to Embodiment 3.

FIG. 14 is a schematic cross-sectional view taken along line H-H of the semiconductor optical integrated element according to Embodiment 3.

FIG. 15 is a schematic cross-sectional view taken along line D-D of the semiconductor optical integrated element according to Embodiment 3.

FIG. 16 is a schematic cross-sectional view taken along line E-E of the semiconductor optical integrated element according to Embodiment 3.

FIG. 17 is a schematic cross-sectional view taken along line I-I of the semiconductor optical integrated element according to Embodiment 3.

FIG. 18 is a schematic cross-sectional view taken along line B-B of a semiconductor optical integrated element according to Embodiment 4.

FIG. 19 is a schematic cross-sectional view taken along line C-C of the semiconductor optical integrated element according to Embodiment 4.

FIG. 20 is a schematic cross-sectional view taken along line J-J of the semiconductor optical integrated element according to Embodiment 4.

### MODE FOR CARRYING OUT INVENTION

Hereinafter, an example of a semiconductor optical integrated element according to the present disclosure will be described, but the present disclosure is not limited to the embodiments described below, and can be implemented with any variation without departing from the gist of the present disclosure. In addition, for convenience, a repetitive description may be omitted.

### Embodiment 1

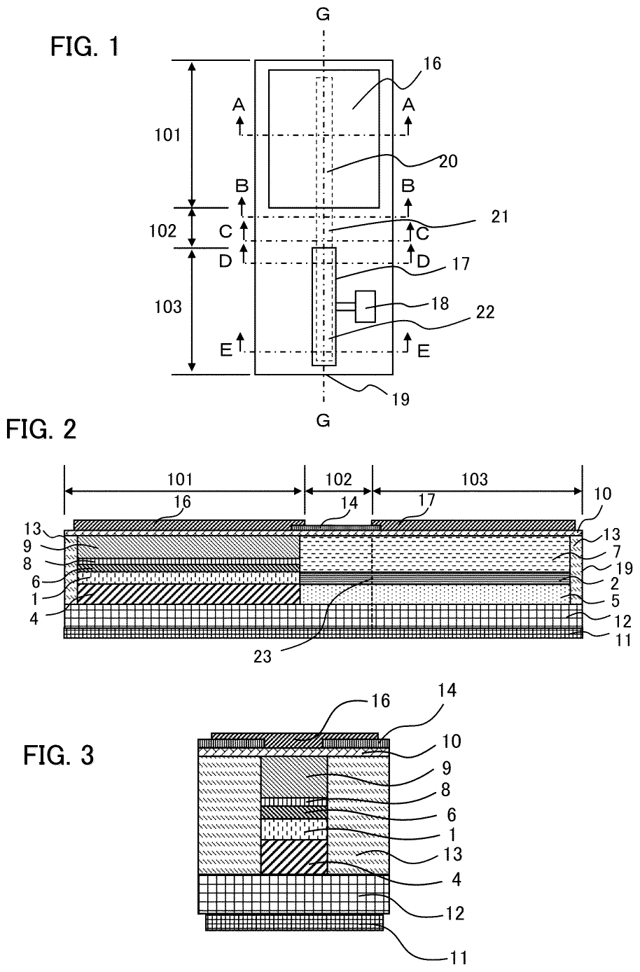

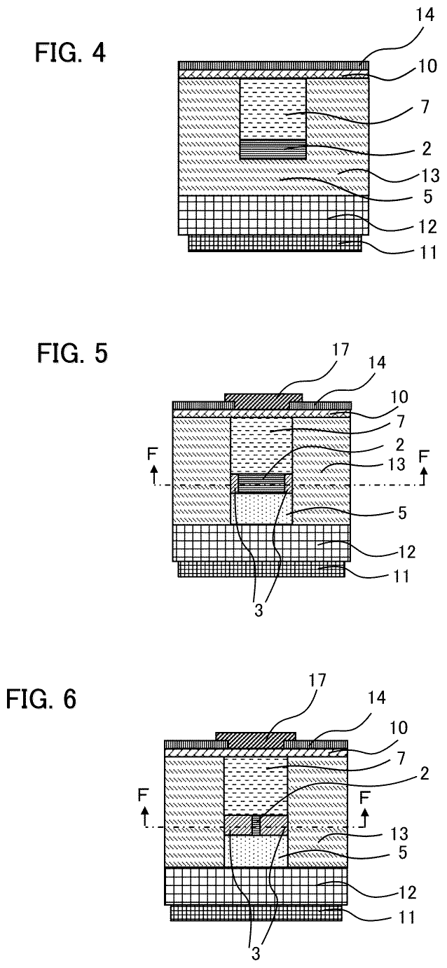

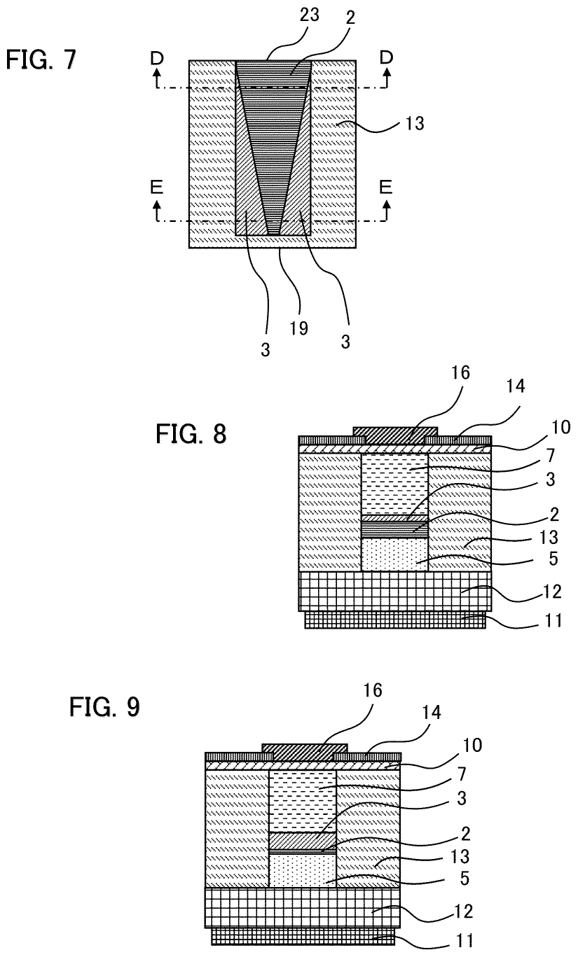

FIG. 1 is a schematic top view of a semiconductor optical integrated element according to Embodiment 1. FIG. 2 is a schematic cross-sectional view taken along line G-G of the semiconductor optical integrated element shown in FIG. 1 according to Embodiment 1. FIG. 3 is a schematic cross-sectional view taken along line A-A of the semiconductor optical integrated element shown in FIG. 1 according to Embodiment 1. FIG. 4 is a schematic cross-sectional view taken along line B-B (and a schematic cross-sectional view taken along line C-C) of the semiconductor optical integrated element shown in FIG. 1 according to Embodiment 1. FIG. 5 is a schematic cross-sectional view taken along line D-D of the semiconductor optical integrated element shown in FIG. 1 according to Embodiment 1. FIG. 6 is a schematic cross-sectional view taken along line E-E of the semiconductor optical integrated element shown in FIG. 1 according to Embodiment 1. FIG. 7 is a schematic cross-sectional view taken along line F-F of an optical modulator portion 103 of the semiconductor optical integrated element shown in FIG. 5 and FIG. 6 according to Embodiment 1. As shown in FIG. 1 and FIG. 2, the semiconductor optical integrated element according to Embodiment 1 includes a laser diode portion 101 that generates laser light, an optical modulator portion 103 that modulates the laser light generated by the laser diode portion 101, and a separation portion 102 that electrically separates the laser diode portion 101 and the optical modulator portion 103.

As shown in FIG. 2 and FIG. 3, the laser diode portion 101 is configured as a structure in which an n-type InP first cladding layer 4, a laser diode portion core layer 1, a p-type InP first cladding layer 6, a diffraction grating 8, and an n-type InP fourth cladding layer 9 are stacked on one face of an n-type InP substrate 12. Note that, here, unless otherwise specified, the direction of the face of the n-type InP substrate 12 on which the semiconductor layers are stacked is referred to as an upward direction, and faces in the direction perpendicular to the upward direction and the propagation direction of the laser light are referred to as side faces. Further, a first optical waveguide 20 shown in FIG. 1 is the optical waveguide including the n-type InP first cladding layer 4, the laser diode portion core layer 1, and the p-type InP first cladding layer 6. Both side face portions of the laser diode portion core layer 1 through which laser light propagates have buried structures in which they are buried with a semiconductor buried layer 13. The semiconductor buried layer 13 may be formed of p-type InP and n-type InP, or a semiconductor such as Fe-doped InP may be used. A p-type first contact layer 10 is stacked on the upper faces of the n-type InP fourth cladding layer 9 and the semiconductor buried layer 13, and a protective passivation film 14 is formed on the upper face of the p-type first contact layer 10. Further, an electrode 16 as an anode electrode is formed on the protective passivation film 14, and the electrode 16 and the p-type first contact layer 10 are electrically connected to each other through an opening formed in the protective passivation film 14. A first electrode 11, which is a cathode electrode, is provided on the lower face side, which is the other face of the n-type InP substrate 12, and the first electrode 11 and the n-type InP substrate 12 are electrically connected to each other.

As shown in FIG. 2 and FIG. 4, the separation portion 102 is configured as a structure in which an n-type InP second cladding layer 5, a first waveguide core layer 2, and a p-type InP second cladding layer 7 are stacked on the n-type InP substrate 12. Further, a second optical waveguide 21 shown in FIG. 1 indicates the optical waveguide including the n-type InP second cladding layer 5, the first waveguide core layer 2, and the p-type InP second cladding layer 7. Both side face portions of the first waveguide core layer 2 have buried structures in which they are buried with the semiconductor buried layer 13. The p-type first contact layer 10 is stacked on the upper faces of the p-type InP second cladding layer 7 and the semiconductor buried layer 13, and the protective passivation film 14 is formed on the upper face of the p-type first contact layer 10. The first electrode 11, which is the cathode electrode, is provided on the lower face side, which is the other face of the n-type InP substrate 12. Note that the second optical waveguide may have a high-mesa ridge structure.

As shown in FIG. 1, FIG. 2, FIG. 5, FIG. 6, and FIG. 7, the optical modulator portion 103 is configured as a structure in which the n-type InP second cladding layer 5, an optical modulator portion core layer 3 and the first waveguide core layer 2, and the p-type InP second cladding layer 7 are stacked on the n-type InP substrate 12. In addition, a third optical waveguide 22 shown in FIG. 1 indicates the optical waveguide including the n-type InP second cladding layer 5, the optical modulator portion core layer 3 and the first waveguide core layer 2, and the p-type InP second cladding layer 7. Both side face portions of the third optical waveguide 22 have buried structures in which they are buried with the semiconductor buried layer 13, similarly to both side face portions of the first waveguide core layer 2. The p-type first contact layer 10 is stacked on the upper faces of the p-type InP second cladding layer 7 and the semiconductor buried layer 13, and the protective passivation film 14 is formed on the upper face of the p-type first contact layer 10. Further, the electrode 16 as an anode electrode is formed on the protective passivation film 14, and an electrode 17 and the p-type first contact layer 10 are electrically connected to each other through an opening formed in the protective passivation film 14. The first electrode 11 is provided on the lower face side of the n-type InP substrate 12 and is electrically connected to the n-type InP substrate 12. The third optical waveguide 22 may have the high-mesa ridge structure. In addition, as shown in FIG. 6, the optical modulator portion 103 has a structure in which the distance between the side faces of the first waveguide core layer 2, that is, the width of the first waveguide core layer 2 with respect to the propagation direction of the laser light narrows from an incident side of the laser light connected to the separation portion 102 toward the side of an emission end face 19 of the laser light. On the other hand, since the width of the third optical waveguide 22 with respect to the propagation direction of the laser light is constant, the width of the optical modulator portion core layer 3 increases with respect to the propagation direction of the laser light in accordance with the decrease in the width of the first waveguide core layer 2 with respect to the propagation direction of the laser light. Although FIG. 6 shows a case where the width of the first waveguide core layer 2 continuously decreases from the incident side of the laser light toward the side of the emission end face 19 of the laser light, the width may be formed in a stepwise shape having steps or may be a combination of a continuous structure and a stepwise structure.

Next, the basic operation of the above-described semiconductor optical integrated element will be described. When a forward current is supplied to the laser diode portion 101, laser oscillation occurs, and laser light is emitted from the laser diode portion 101. The laser light enters the separation portion 102, propagates through the optical modulator portion 103, and is emitted from the emission end face 19 to the outside. The laser diode portion 101 is configured as, for example, a distributed feedback laser structure. The distributed feedback laser structure is provided with the diffraction grating 8, and laser light of single mode oscillation can be obtained by the diffraction grating 8. The optical modulator portion 103 is an electro-absorption modulator that controls the amount of light absorption by an electric field, and the amount of light absorption increases when a reverse bias voltage is applied. That is, the laser light inputted is modulated depending on the magnitude of the voltage applied to the optical modulator portion 103. When light is absorbed, the absorbed light is converted into carriers, and thus a current flows as a photocurrent.

Next, more specific operations and effects of the semiconductor optical integrated element according to Embodiment 1 will be described. First, with regard to the concentration of the light absorption current in the vicinity of the incident end face of the optical modulator portion where the light intensity is highest, the concentration of the light absorption current in a microscopic region can be suppressed by reducing the amount of light absorption in the vicinity of the incident end face of the optical modulator portion. Specifically, it is conceivable that the intensity of the light incident on the optical modulator portion core layer where the light absorption occurs is reduced at the incident end face of the optical modulator portion where the intensity of the light is high. Here, inside the optical modulator portion, the light absorption by the optical modulator portion core layer occurs in the axial direction of the optical waveguide, and thus the relationship between the length of the optical waveguide from the light incident end and the light intensity is expressed by the following equation (1).

$$P ( x ) = P ( 0 ) exp ( - Γ α x ) \qquad ( 1 )$$

Γ is a light confinement factor of the optical modulator portion core layer, a is an absorption coefficient of the optical modulator portion core layer, x is the length of the optical waveguide from the light incident end, and P (0) is an intensity of the incident light. That is, when Γ and α are constants with respect to x, the incident light decreases exponentially from the incident end of the optical waveguide toward the emission direction. In other words, the amount of light absorption at a certain x also decreases exponentially from the incident end of the optical waveguide toward the emission direction. Therefore, in the optical waveguide of the electro-absorption (EA) modulator, by adopting a structure in which Γ is decreased on the incident side where the intensity of light is high and Γ is continuously increased toward the emission side, it is possible to reduce the light absorption current on the incident side where the intensity of light is high. This makes it possible to average the amount of light absorption per unit area along the optical axis direction, thereby suppressing the increase in the light absorption current density on the incident side as compared with the conventional products.

In the semiconductor optical integrated element according to Embodiment 1, the third optical waveguide 22 of the optical modulator portion 103 buries both side face portions of the first waveguide core layer 2 that does not function as a light absorption layer with the optical modulator portion core layer 3, which functions as the light absorption layer, as shown in FIG. 5, FIG. 6, and FIG. 7. Furthermore, in the vertical cross-section of the third optical waveguide 22 with respect to the optical axis, the proportion of the cross-sectional area of the optical modulator portion core layer 3 increases from the light incident side to the light emission side. In other words, as the light incident on the third optical waveguide 22 propagates from the incident side to the emission side, the proportion of light interacting with the optical modulator portion core layer 3 increases. This means that the effective light confinement factor Γ of the third optical waveguide 22 also increases from the light incident side to the light emission side. Since the amount of light absorption correlates with the light confinement factor T, the third optical waveguide 22 configured in this manner can suppress the amount of light absorption on the side of an incident end face 23 compared to the side of the emission end face of the light while the thickness of the third optical waveguide 22 is kept constant. Note that the term “maintaining a constant thickness” as used herein means that the thickness does not change as intended by the design. That is, it does not mean that the thickness is strictly constant, but includes a case where the thickness is substantially constant. As a specific example of the first waveguide core layer 2 and the optical modulator portion core layer 3, for example, the total width of the first waveguide core layer 2 and the optical modulator portion core layer 3 is set to about 2 μm, the width of the first waveguide core layer 2 on the side of the incident end face 23 is set to about 2 μm, and the width thereof on the side of the emission end face is set to about 0.4 μm. Note that the width of the first waveguide core layer 2 of the optical modulator portion 103 may have not only a tapered shape in which the width continuously narrows from the light incident side toward the light emission side but also a shape in which the width narrows in a stepwise shape having steps. In addition, the first waveguide core layer 2 of the optical modulator portion 103 may be extended to the end face of the semiconductor optical integrated element. Furthermore, the first waveguide core layer 2 of the optical modulator portion 103 may be grown together with the optical waveguide layer of the separation portion 102, or it may be grown separately. The semiconductor buried layer 13 may be composed of the p-type InP and the n-type InP, or a semiconductor such as the Fe-doped InP may be used. Furthermore, the laser diode portion core layer 1 of the laser diode portion 101 is composed of, for example, an InGaAsP-based multiple quantum well layer, with a bandgap wavelength of approximately 1.2 to 1.6 μm. The bandgap wavelength of the first waveguide core layer 2 in the separation portion 102 and the optical modulator portion 103 should be set shorter than the wavelength of the laser oscillated from the laser diode portion 101, and for example, it is approximately 0.9 to 1.5 μm. The bandgap wavelength of the optical modulator core layer 3 in the optical modulator portion 103 should be set to be shorter than the wavelength of the laser oscillated from the laser diode portion 101. For example, the optical modulator core layer 3 is composed of an InGaAsP-based multiple quantum well layer with a bandgap wavelength of approximately 0.9 to 1.5 μm. The bandgap wavelength of the optical modulator core layer 3 may remain constant from the incident side to the emission side, or it may be increased continuously or stepwise. The formation of the laser diode portion core layer 1 and the optical modulator portion core layer 3 may be carried out using selective growth technology, or alternatively, they may be separately formed by Butt-Joint growth.

Next, a method of manufacturing the semiconductor optical integrated element according to Embodiment 1 will be described. In the region where the laser diode portion 101 is formed, the n-type InP first cladding layer 4, the laser diode portion core layer 1, the p-type InP first cladding layer 6, the diffraction grating 8, and the n-type InP fourth cladding layer 9 are stacked on the n-type InP substrate 12. In the region where the separation portion 102 and the optical modulator portion 103 are formed, the n-type InP second cladding layer 5 and the first waveguide core layer 2 are stacked on the n-type InP substrate 12. Subsequently, an insulating film is formed on the upper face of the first waveguide core layer 2, and the insulating film is patterned such that the insulating film remains in a shape corresponding to the first waveguide core layer 2 shown in FIG. 7. The first waveguide core layer 2 of the optical modulator portion 103 is etched by using an etching technique such as dry etching with the insulating film as an etching mask, thereby forming the first waveguide core layer 2 having the shape shown in FIG. 7. Next, both side face portions of the first waveguide core layer 2 of the optical modulator portion 103 are buried with the optical modulator portion core layer 3. Thereafter, the insulating film used as the etching mask is removed, and the p-type InP second cladding layer 7 of the separation portion 102 and the optical modulator portion 103 is stacked. Next, an insulating film is formed on the upper faces of the n-type InP fourth cladding layer 9 of the laser diode portion 101, the p-type InP second cladding layer 7 of the separation portion 102, and the p-type InP second cladding layer 7 of the optical modulator portion 103, and the insulating film is patterned into shapes corresponding to the respective ridge structures of the first optical waveguide 20, the second optical waveguide 21, and the third optical waveguide 22. The ridge structures of the first optical waveguide 20, the second optical waveguide 21, and the third optical waveguide 22 are formed by using an etching technique such as dry etching with the insulating film as an etching mask. Next, both side face portions of the ridge structures of the laser diode portion 101, the separation portion 102, and the optical modulator portion 103 are buried with the semiconductor buried layer 13. The semiconductor buried layer 13 may be formed of the p-type InP and the n-type InP, or a semiconductor such as the Fe-doped InP may be used. Thereafter, the insulating film is removed, and the p-type first contact layer 10 is stacked. Next, the protective passivation film 14 is formed on the upper face of the p-type first contact layer 10. An opening is formed in the protective passivation film 14 on the upper face of the laser diode portion 101, and the electrode 16 electrically connected to the p-type first contact layer 10 is formed. Further, an opening is formed in the protective passivation film 14 on the upper face of the optical modulator portion 103, and the electrode 17 electrically connected to the p-type first contact layer 10 and a bonding pad 18 electrically connected to the electrode 17 are formed.

As described above, the semiconductor optical integrated element according to Embodiment 1 has a structure in which both side face portions of the first waveguide core layer 2 that does not function as a light absorption layer are buried with the optical modulator portion core layer 3 that functions as the light absorption layer while the thickness of the third optical waveguide 22 of the optical modulator portion 103 is kept constant. That is, the optical modulator portion core layer 3 is structured to be positioned such that it interposes the first waveguide core layer 2 from the sides toward the propagation direction of the laser light. Further, the structure is such that, in the vertical cross section of the third optical waveguide 22 with respect to the optical axis, the proportion of the cross-sectional area of the optical modulator portion core layer 3 increases from the light incident side toward the light emission side. The semiconductor optical integrated element configured in this manner can suppress the amount of light absorption on the side of the incident end face 23 as compared with the side of the light emission end face 19 while the thickness of the third optical waveguide 22 is kept constant.

Therefore, by applying the semiconductor optical integrated element shown in Embodiment 1, it is possible to suppress the light with intensity staying high from being incident on the light absorption layer in the vicinity of the incident end face 23 of the optical modulator portion, and thus it is possible to provide a semiconductor optical integrated element that prevents characteristic degradation caused by the concentration of the light absorption current on a microscopic region.

### Embodiment 2

A semiconductor optical integrated element according to Embodiment 2 will be described below. Since the configuration of the semiconductor optical integrated element according to Embodiment 2 is the same as that of Embodiment 1 except for the structure of the optical modulator portion 103, the differences from Embodiment 1 are mainly shown, and a repetitive description may be omitted.

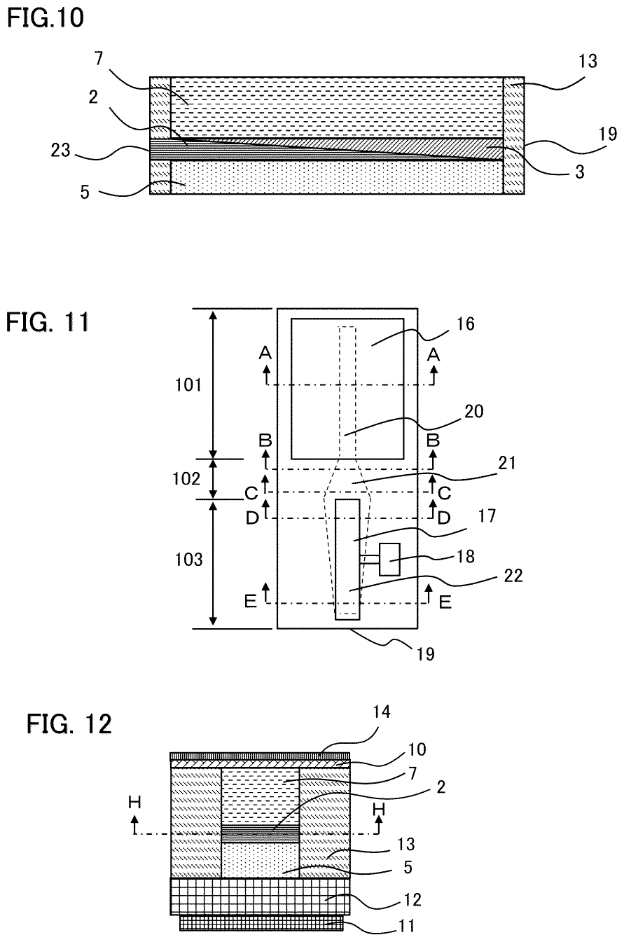

A schematic top view of the semiconductor optical integrated element according to Embodiment 2 is the same as FIG. 1. FIG. 8 is a schematic cross-sectional view taken along line D-D of the semiconductor optical integrated element shown in FIG. 1 according to Embodiment 2. FIG. 9 is a schematic cross-sectional view taken along line E-E of the semiconductor optical integrated element shown in FIG. 1 according to Embodiment 2. FIG. 10 is a schematic cross-sectional view taken along line G-G of the optical modulator portion 103 of the semiconductor optical integrated element shown in FIG. 1 according to Embodiment 2. As shown in FIG. 8 to FIG. 10, the optical modulator portion 103 of the semiconductor optical integrated element according to Embodiment 2 is configured as a structure in which the n-type InP second cladding layer 5, the first waveguide core layer 2, the optical modulator portion core layer 3, and the p-type InP second cladding layer 7 are stacked on the n-type InP substrate 12. The first waveguide core layer 2 has a structure in which the thickness in the stacking direction of the third optical waveguide 22, that is, the thickness in the vertical direction is continuously reduced from the incident side of the laser light toward the side of the emission end face 19 of the laser light. On the other hand, since the thickness of the third optical waveguide 22 is constant, the thickness of the optical modulator portion core layer 3 increases toward the propagation direction of the laser light in accordance with the decrease in the thickness of the first waveguide core layer 2 with respect to the propagation direction of the laser light. Although the thicknesses of the first waveguide core layer 2 and the optical modulator portion core layer 3 are continuously changed along the propagation direction of the laser light, the thicknesses may be changed in a stepwise manner having steps or may be changed in a combination of a continuous manner and a stepwise manner. The order of stacking the first waveguide core layer 2 and the optical modulator portion core layer 3 may be reversed.

As described above, the semiconductor optical integrated element according to Embodiment 2 has a structure in which the first waveguide core layer 2 that does not function as the light absorption layer and the optical modulator portion core layer 3 are stacked in the vertical direction while the thickness of the third optical waveguide 22 of the optical modulator portion 103 is kept constant. Further, the thickness of the optical modulator portion core layer 3 increases toward the propagation direction of the laser light. That is, in the vertical cross-section of the third optical waveguide 22 with respect to the optical axis, the proportion of the cross-sectional area of the optical modulator portion core layer 3 increases from the light incident side toward the light emission side. The semiconductor optical integrated element configured in this manner can suppress the amount of light absorption on the side of the incident end face 23 as compared with the side of the light emission end face 19 while the thickness of the third optical waveguide 22 is kept constant.

Therefore, by applying the semiconductor optical integrated element shown in Embodiment 2, it is possible to suppress the light with intensity staying high from being incident on the light absorption layer in the vicinity of the incident end face 23 of the optical modulator portion, as in Embodiment 1, and thus it is possible to provide a semiconductor optical integrated element that prevents the characteristic degradation caused by the concentration of the light absorption current on a microscopic region.

### Embodiment 3

A semiconductor optical integrated element according to Embodiment 3 will be described below. Note that the configuration of the semiconductor optical integrated element according to Embodiment 3 is different from those of Embodiment 1 in the structures of the separation portion 102 and the optical modulator portion 103. Differences from Embodiment 1 are mainly described, and a repetitive description may be omitted.

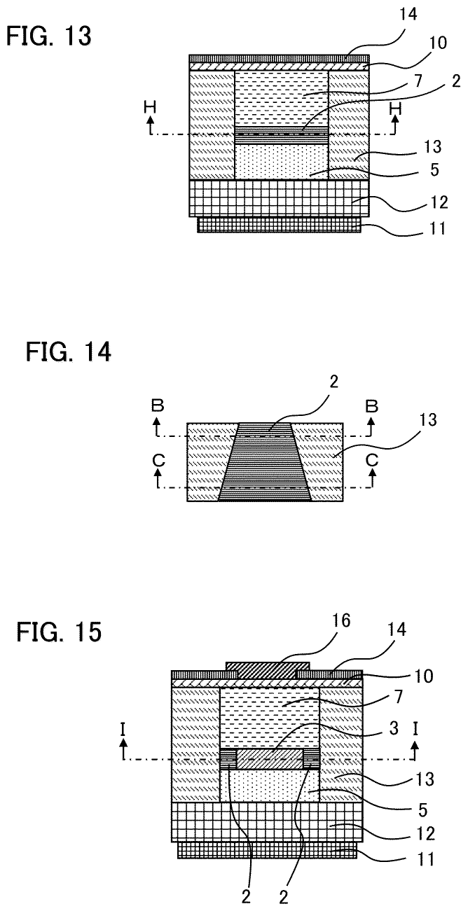

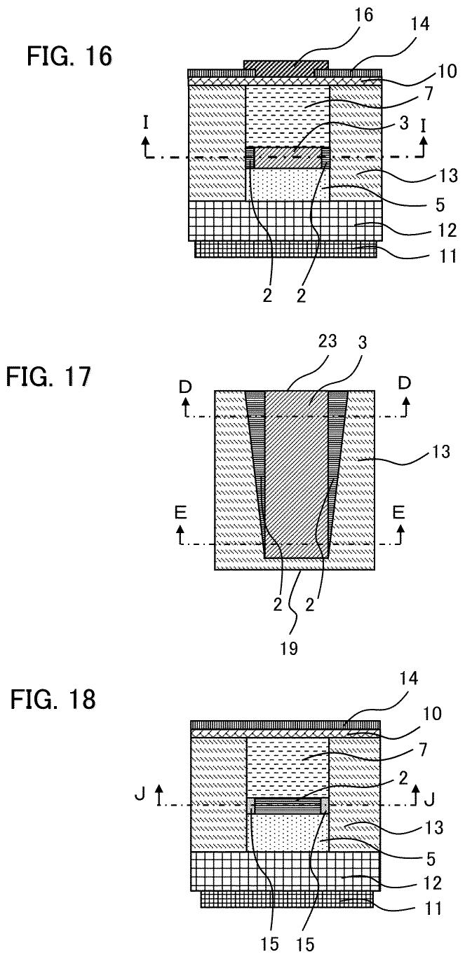

FIG. 11 is a schematic top view showing the semiconductor optical integrated element according to Embodiment 3. FIG. 12 is a schematic cross-sectional view taken along line B-B of the separation portion 102 shown in FIG. 11 of the semiconductor optical integrated element according to Embodiment 3. FIG. 13 is a schematic cross-sectional view taken along line C-C of the separation portion 102 shown in FIG. 11 of the semiconductor optical integrated element according to Embodiment 3. FIG. 14 is a schematic cross-sectional view taken along line H-H of the separation portion 102 shown in FIG. 12 and FIG. 13 of the semiconductor optical integrated element according to Embodiment 3. FIG. 15 is a schematic cross-sectional view taken along line D-D of the optical modulator portion 103 shown in FIG. 11 of the semiconductor optical integrated element according to Embodiment 3. FIG. 16 is a schematic cross-sectional view taken along line E-E of the optical modulator portion 103 shown in FIG. 11 of the semiconductor optical integrated element according to Embodiment 3. FIG. 17 is a schematic cross-sectional view taken along line I-I of the optical modulator portion 103 shown in FIG. 15 and FIG. 16 of the semiconductor optical integrated element according to Embodiment 3. First, as shown in FIG. 11 to FIG. 14, the separation portion 102 of the semiconductor optical integrated element according to Embodiment 3 has a structure in which the width of the second optical waveguide 21 with respect to the propagation direction of the laser light increases toward the propagation direction of the laser light. Further, as shown in FIG. 15 to FIG. 17, the optical modulator portion 103 of the semiconductor optical integrated element according to Embodiment 3 has a structure in which the width of the third optical waveguide 22 with respect to the propagation direction of the laser light narrows toward the propagation direction of the laser light. However, the third optical waveguide 22 has a structure in which the height is constant, the optical modulator portion core layer 3 having a constant width is formed in the central portion along the propagation direction of the laser light, and both side faces of the optical modulator portion core layer 3 are buried with the first waveguide core layer 2. Furthermore, the first waveguide core layer 2 buried in both side faces of the optical modulator portion core layer 3 has a width that decreases along the propagation direction of the laser light. Note that, although FIG. 17 shows a case where the width of the first waveguide core layer 2 narrows continuously along the propagation direction of the laser light, the first waveguide core layer 2 may be formed in a stepwise shape having steps or may be a combination of a continuous structure and a stepwise structure.

As described above, in the semiconductor optical integrated element according to Embodiment 3, the width of the second optical waveguide 21 of the separation portion 102 increases from the light incident side toward the light emission side. This makes it possible to reduce the light confinement factor Γ at the incident end face 23 of the optical modulator portion 103 and to reduce the intensity of light per unit area, as compared with the case where the width of the second optical waveguide 21 is constant. In addition, the width of the first waveguide core layer 2 of the optical modulator portion 103 narrows from the light incident side toward the light emission side. This makes it possible to increase the light confinement factor Γ of the optical modulator portion core layer 3 from the light incident side toward the light emission side. Therefore, the intensity of the light can be reduced by the laser light passing through the separation portion 102, and further, in the optical modulator portion 103, the amount of absorption of the light on the side of the incident end face 23 can be suppressed as compared with the side of the emission end face 19 of the light. As a result, the concentration of the light absorption current in the vicinity of the incident end face 23 of the optical modulator portion 103 can be reduced as compared with the conventional semiconductor optical integrated element.

As described above, in the semiconductor optical integrated element according to Embodiment 3, the width of the second optical waveguide 21 of the separation portion 102 increases from the light incident side toward the light emission side. Further, the width of the first waveguide core layer 2 of the optical modulator portion 103 narrows from the light incident side toward the light emission side, and in the vertical cross section of the third optical waveguide 22 with respect to the optical axis, the proportion of the cross-sectional area of the optical modulator portion core layer 3 increases from the light incident side toward the light emission side. The semiconductor optical integrated element configured in this manner can suppress the amount of light absorption on the side of the incident end face 23 as compared with the side of the light emission end face 19 while the thickness of the third optical waveguide 22 is kept constant.

Therefore, by applying the semiconductor optical integrated element shown in Embodiment 3, it is possible to suppress the light with intensity staying high from being incident on the light absorption layer in the vicinity of the incident end face 23 of the optical modulator portion, as in Embodiment 1, and thus it is possible to provide a semiconductor optical integrated element that prevents the characteristic degradation caused by the concentration of the light absorption current on a microscopic region.

### Embodiment 4

A semiconductor optical integrated element according to Embodiment 4 will be described below. Note that the configuration of the semiconductor optical integrated element according to Embodiment 4 is the same as that of Embodiment 3 except for the structure of the separation portion 102, and thus the differences from Embodiment 3 are mainly described, and a repetitive description may be omitted.

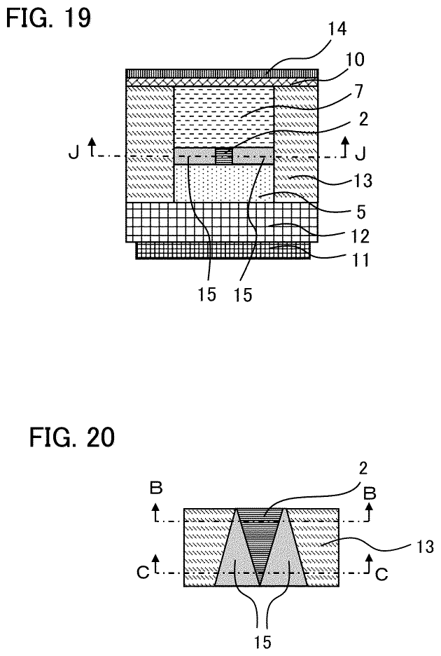

A schematic top view of the semiconductor optical integrated element according to Embodiment 4 is the same as FIG. 11. FIG. 18 is a schematic cross-sectional view taken along line B-B of the separation portion 102 shown in FIG. 11 of the semiconductor optical integrated element according to Embodiment 4. FIG. 19 is a schematic cross-sectional view taken along line C-C of the separation portion 102 shown in FIG. 11 of the semiconductor optical integrated element according to Embodiment 4. FIG. 20 is a schematic cross-sectional view taken along line J-J of the separation portion 102 shown in FIG. 18 and FIG. 19 of the semiconductor optical integrated element according to Embodiment 4. In the semiconductor optical integrated element according to Embodiment 4, the separation portion 102 is configured as a structure in which the n-type InP second cladding layer 5, the first waveguide core layer 2 and a second waveguide core layer 15, and the p-type InP second cladding layer 7 are stacked on the n-type InP substrate 12. Further, the first electrode 11, which is a cathode electrode, is provided on the lower face of the n-type InP substrate 12, and the first electrode 11 and the n-type InP substrate 12 are electrically connected to each other. Note that the second optical waveguide 21 shown in FIG. 11 indicates the optical waveguide including the n-type InP second cladding layer 5, the first waveguide core layer 2 and the second waveguide core layer 15, and the p-type InP second cladding layer 7.

The width of the first waveguide core layer 2 of the separation portion 102 continuously narrows from the incident side of the laser light toward the emission side of the laser light. Note that the width of the first waveguide core layer 2 of the separation portion 102 may not be a tapered shape in which the width continuously narrows from the light incident side toward the light emission side but a shape in which the width narrows in a stepwise shape having steps. The width of the second waveguide core layer 15 of the separation portion 102 continuously increases. Note that the width of the second waveguide core layer 15 may not be an inversely tapered shape in which the width continuously increases from the light incident side toward the light emission side but a shape in which the width increases in a stepwise shape having steps. Here, semiconductors with different bandgap wavelengths from each other are applied to the semiconductor constituting the first waveguide core layer 2 and the semiconductor constituting the second waveguide core layer 15, so that the beam diameter of the laser light by passing through the second optical waveguide 21 can be controlled. For example, the first waveguide core layer 2 is made of an InGaAsP-based material having a bandgap wavelength of about 0.9 to 1.5 μm, and the second waveguide core layer 15 is made of an InP-based material having a bandgap wavelength of about 0.9 to 1.0 μm, so that the spread and coupling of the laser light can be changed.

As described above, in the semiconductor optical integrated element according to Embodiment 4, the width of the second optical waveguide 21 of the separation portion 102 increases from the light incident side toward the light emission side, as in Embodiment 43. Additionally, it is possible to apply the first waveguide core layer 2 and the second waveguide core layer 15, which are semiconductors with different bandgap wavelengths. Accordingly, compared to the case where the width of the second optical waveguide 21 is constant, the light confinement factor Γ at the incident end face 23 of the optical modulator portion 103 can be reduced, the intensity of light per unit area can be reduced, and laser light can be coupled more efficiently than in Embodiment 3 to be incident on the optical modulator portion 103. As a result, it is possible to reduce the concentration of the light absorption current in the vicinity of the incident end face 23 of the optical modulator portion 103 as compared with the conventional semiconductor optical integrated element while the laser light is more efficiently coupled as compared with Embodiment 3.

As described above, in the semiconductor optical integrated element according to Embodiment 4, the width of the first waveguide core layer 2 of the separation portion 102 narrows from the incident side of the laser light toward the emission side of the laser light, and the width of the second waveguide core layer 15 continuously increases. Further, semiconductors with different bandgap wavelengths from each other are applied to the semiconductor constituting the first waveguide core layer 2 and the semiconductor constituting the second waveguide core layer 15. This makes it possible to couple the laser light more efficiently than in Embodiment 3 and cause the laser light to be incident on the optical modulator portion 103. Further, similarly to Embodiment 3, the width of the first waveguide core layer 2 of the optical modulator portion 103 narrows from the light incident side toward the light emission side, and in the vertical cross section of the third optical waveguide 22 with respect to the optical axis, the proportion of the cross-sectional area of the optical modulator portion core layer 3 increases from the light incident side toward the light emission side. The semiconductor optical integrated element configured in this manner can suppress the amount of light absorption on the side of the incident end face 23 as compared with the side of the light emission end face 19 while the thickness of the third optical waveguide 22 is kept constant, and furthermore it can couple laser light more efficiently as compared with that of Embodiment 3.

Therefore, by applying the semiconductor optical integrated element shown in Embodiment 4, as in Embodiment 3, it is possible to suppress the light with intensity staying high from being incident on the light absorption layer in the vicinity of the incident end face 23 of the optical modulator portion, and thus it is possible to provide a semiconductor optical integrated element capable of preventing the characteristic degradation caused by the concentration of the light absorption current on a microscopic region and further capable of efficiently coupling laser light.

### DESCRIPTION OF REFERENCE NUMERALS AND SIGN

1: laser diode portion core layer, 2: first waveguide core layer, 3: optical modulator portion core layer, 4: n-type InP first cladding layer, 5: n-type InP second cladding layer, 6: p-type InP first cladding layer, 7: p-type InP second cladding layer, 8: diffraction grating, 9: n-type InP fourth cladding layer, 10: p-type first contact layer, 11: first electrode, 12: n-type InP substrate, 13: semiconductor buried layer, 14: protective passivation film, 15: second waveguide core layer, 16: electrode, 17: electrode. 18: bonding pad, 19: emission end face, 20: first optical waveguide, 21: second optical waveguide, 22: third optical waveguide, 23 incident end face, 101: laser diode portion, 102: separation portion, 103: optical modulator portion

1. A semiconductor optical integrated element comprising:
a laser diode portion that includes a first optical waveguide and generates laser light;
a separation portion connected to the laser diode portion and including a second optical waveguide that has a first core layer to propagate laser light emitted from the laser diode portion; and
an optical modulator portion connected to the separation portion and including a third optical waveguide that has a second core layer to absorb a part of the laser light emitted from the separation portion, wherein
the third optical waveguide has a constant thickness in a direction perpendicular to a face of a substrate on which the optical modulator portion is formed,
a proportion of the second core layer in a cross section of the third optical waveguide perpendicular to a propagation direction of the laser light increases from an incident side of the laser light toward an emission side of the laser light, and
at an incident end face of the optical modulator portion, the third optical waveguide includes the first core layer or a third core layer that does not contribute to absorption of the laser light.

2. The semiconductor optical integrated element according to claim 1, wherein the third optical waveguide includes the first core layer and the second core layer, the second core layer is provided to be positioned such that the first core layer is interposed from sides toward the propagation direction of the laser light, and a width of the first core layer interposed by the second core layer narrows from the incident side of the laser light toward the emission side the laser light.

3. The semiconductor optical integrated element according to claim 1, wherein the second core layer has a thickness in a direction perpendicular to the face of the substrate on which the optical modulator portion is formed, the thickness increasing from the incident side of the laser light toward the emission side of the laser light.

4. The semiconductor optical integrated element according to claim 1, wherein the second optical waveguide has a width in a direction perpendicular to the propagation direction of the laser light and parallel to the face of the substrate on which the separation portion is formed, the width increasing from the incident side of the laser light toward the emission side of the laser light, the third optical waveguide includes a third core layer, and a width of the third optical waveguide in a direction perpendicular to the propagation direction of the laser light and parallel to the face of the substrate on which the separation portion is formed narrows from the incident side of the laser light toward the emission side of the laser light, and the third core layer is provided to be positioned such that the second core layer is interposed from sides toward the propagation direction of the laser light, and a width of the third core layer narrows from the incident side of the laser light toward the emission side of the laser light.

5. The semiconductor optical integrated element according to claim 4, wherein the second optical waveguide includes a fourth core layer having a bandgap wavelength different from that of the first core layer, the first core layer has a width in the direction perpendicular to the propagation direction of the laser light and parallel to the face of the substrate on which the separation portion is formed, the width decreasing from the incident side of the laser light toward the emission side of the laser light, and the fourth core layer is provided to be positioned such that the first core layer is interposed from sides toward the propagation direction of the laser light, and a width of the fourth core layer increases from the incident side of the laser light toward the emission side of the laser light.

6. The semiconductor optical integrated element according to claim 1, wherein a bandgap wavelength of the second core layer is longer on the emission side of the laser light than on the incident side of the laser light.

7. The semiconductor optical integrated element according to claim 2, wherein a bandgap wavelength of the second core layer is longer on the emission side of the laser light than on the incident side of the laser light.

8. The semiconductor optical integrated element according to claim 3, wherein a bandgap wavelength of the second core layer is longer on the emission side of the laser light than on the incident side of the laser light.

9. The semiconductor optical integrated element according to claim 4, wherein a bandgap wavelength of the second core layer is longer on the emission side of the laser light than on the incident side of the laser light.

10. The semiconductor optical integrated element according to claim 5, wherein a bandgap wavelength of the second core layer is longer on the emission side of the laser light than on the incident side of the laser light.
